(19) United States
(12) Patent Application Publication
(10) Pub. No.: US 2025/0055299 A1
(43) Pub. Date: Feb. 13, 2025

(54) NON-LINEAR CAPACITOR

(71) Applicant: Tymphany HK Limited, Hong Kong (HK)

(72) Inventor: Terry GIVEN, Taipei City (TW)

(21) Appl. No.: 18/639,250

(22) Filed: Apr. 18, 2024

(30) Foreign Application Priority Data
Aug. 11, 2023 (CN) 2023110139128

(51) Int. Cl. H02J 7/00; H02J 7/34

(52) U.S. Cl. CPC H02J 7/00714; H02J 7/345; H02J 2207/50

(57) ABSTRACT

A non-linear capacitor includes a capacitor, a first and a second amplifier devices, and an input and output node for providing a charging current and a discharging current. The capacitor connects to the input and output node through the first and the second amplifier devices. When the capacitor is charging, one of the first and the second amplifier devices is conducted to vary the charging current, and the capacitor is charged by the varied charging current. When the capacitor is discharging, the other of the first and the second amplifier devices is conducted to vary the discharging current, and the capacitor is discharged by the varied discharging current. A variation trend of the charging current is opposite to a variation trend of the discharging current.

### CROSS REFERENCE TO RELATED APPLICATIONS

This application claims priority of application No. 2023110139128 filed in China on Aug. 11, 2023 under 35 U.S.C. § 119, the entire contents of all of which are hereby incorporated by reference.

### TECHNICAL FIELD

The present application relates to the field of circuit technology, in particular, to a non-linear capacitor.

### BACKGROUND

Power-on delay circuits usually has the problem that when the power is turned off, for the non-linear capacitor, the discharging time is at least as long as the turned on delay time, and in most cases, the discharging time is much longer than the delay time.

The turned on delay time can be reduced by rapidly shortening the power cycle. However, in some cases, this method is difficult to implement. In addition, depending on the specific application of the power-on delay circuit, this method may cause a very disadvantageous impact.

### SUMMARY OF THE APPLICATION

For the above problems in the related art, the present application proposes a non-linear capacitor with widely varying effective charging capacitance and effective discharging capacitance, thereby the charging time and the discharging time may be configured more flexibly.

According to embodiments of the present application, a non-linear capacitor is provided, which includes a capacitor, a first amplifier device, a second amplifier device, and an input and output node for providing a charging current and a discharging current. The capacitor connects to the input and output node through the first and the second amplifier devices. When the capacitor is charging, one of the first and the second amplifier devices is conducted to vary the charging current, and the capacitor is charged by the changed charging current, when the capacitor is discharging, the other of the first and the second amplifier devices is conducted to vary the discharging current, and the capacitor is discharged by the varied discharging current, wherein a variation trend of the charging current is opposite to a variation trend of the discharging current.

According to embodiments of the present application, the first amplifier device is a first NPN transistor, and the second amplifier device is a second NPN transistor. An emitter of the first NPN transistor and a base of the second NPN transistor are connected to an end of the capacitor and a base of the first NPN transistor and an emitter of the second NPN transistor are connected to the input and output node.

According to embodiments of the present application, the effective charging capacitance C_{charge} and the effective discharging capacitance C_{discharge} respectively are:

$${C}_{discharge} = ( β 2 + 1 ) C 1 , {C}_{charge} = C 1 / ( β 1 + 1 ) ,$$

wherein β1 is a current gain of the first NPN transistor, and β2 is a current gain of the second NPN transistor.

According to embodiments of the present application, the first NPN transistor and the second NPN transistor are connected as a Darlington pair.

According to embodiments of the present application, the first NPN transistor and the second NPN transistor are connected as a Sziklai pair.

According to embodiments of the present application, the first amplifier device is a first PNP transistor and the second amplifier device is a second PNP transistor. An emitter of the first PNP transistor and a base of the second PNP transistor are connected to an end of the capacitor and a base of the first PNP transistor and an emitter of the second PNP transistor are connected to the input and output node.

According to embodiments of the present application, the effective charging capacitance C_{charge} and the effective discharging capacitance C_{discharge} respectively are:

$${C}_{charge} = ( β 2 + 1 ) C 1 , {C}_{discharge} = C 1 / ( β 1 + 1 ) ,$$

wherein β1 is a current gain of the first PNP transistor, and β2 is a current gain of the second PNP transistor.

According to embodiments of the present application, the first PNP transistor and the second PNP transistor are connected as a Darlington pair.

According to embodiments of the present application, the first PNP transistor and the second PNP transistor are connected as a Sziklai pair.

According to embodiments of the present application, the non-linear capacitor further includes a resistor connected to the input and output node.

According to embodiments of the present application, the non-linear capacitor includes a capacitor, a first transistor, a second transistor, and an input and output node for providing a charging current and a discharging current. An emitter of the first transistor and a base of the second transistor are connected to a first end of the capacitor and a base of the first transistor and the second transistor are connected to the input and output node. One of the first transistor and the second transistor is conducted and the other is cut off when the capacitor is charging and the one of the first transistor and the second transistor is cutoff and the other is conducted when the capacitor is discharging.

According to embodiments of the present application, the first transistor and the second transistor are NPN transistors. The first transistor is conducted when the capacitor is charging and the second transistor is conducted when the capacitor is discharging.

According to embodiments of the present application, the first transistor and the second transistor are PNP transistors. The second transistor is conducted when the capacitor is charging and the first transistor is conducted when the capacitor is discharging.

According to embodiments of the present application, the non-linear capacitor further includes a resistor connected to the input and output node.

According to embodiments of the present application, the first transistor and the second transistor are connected as a Darlington pair or a Sziklai pair.

The beneficial effects of the present application are as follows.

Since a first amplifier device and a second amplifier device connect the capacitor to the input and output node in an alternate conduction manner, and the charging current and the discharging current supplied to the capacitor are inversely changed by the first amplifier device and the second amplifier device, and correspondingly the effective charging capacitance and effective discharging capacitance are inversely changed, the non-linear capacitor of the present application may have widely varying effective charging capacitance and effective discharging capacitance.

### BRIEF DESCRIPTION OF THE ACCOMPANYING DRAWINGS

In order to illustrate the technical solutions in the embodiments of the present application in the prior art more clearly, the drawings which are required to be used in the description of the embodiments of the present application are briefly described below. It is clear that the drawings described below are only some embodiments of the present disclosure. It is apparent to those skilled in the art that other drawings may be obtained based on the accompanying drawings without giving inventive effort.

FIG. 1 is a circuit diagram of a non-linear capacitor according to an embodiment of the present application;

FIG. 2 is a circuit diagram of an equivalent charging and discharging circuits of the circuit in FIG. 1;

FIG. 3A is a diagram of simulation results of the circuit in FIG. 1;

FIG. 3B is a time zoomed diagram of FIG. 3A;

FIG. 4 is a circuit diagram of a non-linear capacitor using Darlington pair according to an embodiment of the present application;

FIG. 5 is a circuit diagram of a non-linear capacitor using Sziklai pair according to an embodiment of the present application;

FIG. 6 is a circuit diagram of a non-linear capacitor with fast charge time and slow discharge time according to an embodiment of the present application;

FIG. 7 is a circuit diagram of a non-linear capacitor using Darlington pair according to an embodiment of the present application; and

FIG. 8 is a circuit diagram of a non-linear capacitor using Sziklai pair according to an embodiment of the present application.

### DETAILED DESCRIPTION OF THE PREFERRED EMBODIMENTS

The technical solutions of the embodiments of the present application will be clearly and completely described in the following with reference to the accompanying drawings. It is clear that the embodiments to be described are only a part the embodiments of the present application rather than all of the embodiments of the present application. All other embodiments obtained by the skilled in the art based on the embodiments of the present application are within the protection scope of the present application.

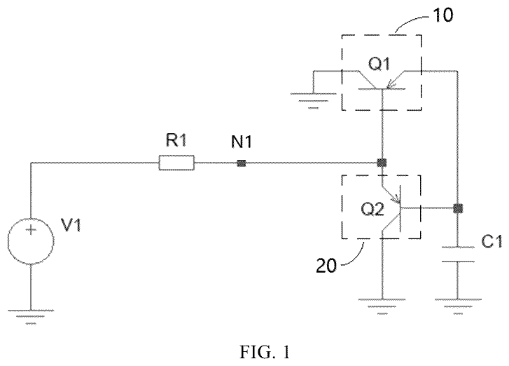

FIG. 1 shows a circuit diagram of a non-linear capacitor according to an embodiment of the present application. As shown in FIG. 1, the non-linear capacitor comprises a capacitor C1, a first amplifier device 10, a second amplifier device 20, and an input and output node N1. The input and output node N1 is used to provide a charging current and a discharging current. The capacitor C1 connects to the input and output node N1 through one of the first amplifier device 10 and the second amplifier device 20. In other words, the second amplifier device 20 is cut off when the first amplifier device 10 is conducted, and the first amplifier device 10 is cut off when the second amplifier device 20 is conducted.

One of the first amplifier device 10 and the second amplifier device 20 (for example, the second amplifier device 20) may be conducted to vary the charging current when the capacitor C1 is charging. The capacitor C1 is charged by the varied charging current.

The other of the first amplifier device 10 and the second amplifier device 20 (for example, the first amplifier device 10) may be conducted to vary the discharging current when the capacitor C1 is discharging. The capacitor C1 is discharged by the varied discharging current. For example, the charging current and the discharging current may be varied by the current gain of the amplifier devices. A variation trend of the charging current is opposite to a variation trend of the discharging current. For example, the charging current increases as the discharging current decreases or the charging current decreases as the discharging current increases. Thereby, the phase difference between the effective charging capacitance and the effective discharging capacitance is increased.

Through the above technical solution of the present application, the variation trends of the effective charging capacitance and the effective discharging capacitance are opposite to each other because the variation trends of the charging current and the discharging current of capacitor C1 are opposite to each other. For example, the effective charging capacitance increases while the effective discharging capacitance decreases. Therefore, the non-linear capacitor of the present application may have widely varying effective charging capacitance and effective discharging capacitance.

Referring to FIG. 1, in an embodiment, the first amplifier device 10 is a first PNP transistor Q1, and the second amplifier device 20 is a second PNP transistor Q2. In other embodiments, the first amplifier device 10 and the second amplifier device 20 may also be implemented by other suitable components or a combination of a plurality of components. An emitter of the first PNP transistor Q1 and a base of the second PNP transistor Q2 are connected to an end of the capacitor C1, and a base of the first PNP transistor Q1 and an emitter of the second PNP transistor Q2 are connected to the input and output node N1. A collector of the first PNP transistor Q1 and a collector of the second PNP transistor Q2 may be respectively connected to reference voltages. In the present embodiment, the collector of the first PNP transistor Q1 and the collector of the second PNP transistor Q2 are grounded respectively. In an embodiment, an asymmetric capacitor of the present application further comprises a first resistor R1. One end of the first resistor R1 is connected to a voltage source V1 and the other end is connected to the input and output node N1. In an embodiment, the first resistor R1 has a resistance of 47kΩ. The resistance of the first resistor R1 may be any other suitable configuration.

When the capacitor C1 is charging, the first PNP transistor Q1 is reverse biased to be cut off. The second PNP transistor Q2 is conducted. Thus, the second PNP transistor Q2 may increase the effective capacitance of the capacitor C1 when the capacitor C1 is charging. Specifically, a charging current I_{charge} from the input and output node N1 provides an emitter current Iₑ₂ for the second PNP transistor Q2, a base current I_{b2} of the second PNP transistor Q2 charges the capacitor C1, and a collector current I_{c2} of the second PNP transistor Q2 is shunted to 0V. Since the operation of the second PNP transistor Q2 satisfies the following formula:

Iₑ₂=1_{b2}+I_{c2} and I_{c2}=β2·I_{b2}, wherein β2 is a current gain of the second PNP transistor Q2.

Therefore, the charging current I_{charge} from the input and output node N1 satisfies I_{charge}=(β₂+1)·I_{b2}. Thus, the current gain of the second PNP transistor Q2 decreases the base current I_{b2} that is the charging current of the capacitor C1, the resultant effective charging capacitance C_{charge} satisfies:

$${C}_{charge} = ( {β}_{2} + 1 ) \cdot C 1. \qquad ( 1 )$$

When the capacitor C1 is discharging, the second PNP transistor Q2 is reverse biased to be cut off, and the first PNP transistor Q1 is conducted. The first PNP transistor Q1 may decrease the effective capacitance of the capacitor C1 when the capacitor C1 is discharging. Specifically, a discharging current I_{discharge} from the input and output node N1 provides the base current I_{b1} for the first PNP transistor Q1. The emitter current Iₑ₁ of the first PNP transistor Q1 is used as the discharging current of the capacitor C1 so as to discharge the capacitor C1, and the collector current Iₑ₁ is shunted to 0V. Similarly, the operation of the second PNP transistor Q2 satisfies the following formula:

Iₑ₁=I_{b1}+I_{c1} and I_{c1}=β₁·I_{b1}, wherein β₁ is a current gain of the first PNP transistor Q1. Thus, the discharging current I_{discharge}=Iₑ₁/(β₁+1).

Since the current gain of the first PNP transistor Q1 increases the discharging current of the capacitor C1, the resultant effective discharging capacitance is:

$${C}_{discharge} = C 1 / ( β 1 + 1 ) . \qquad ( 2 )$$

It is clear that the non-linear capacitor of the present application provides a widely varying effective charging capacitance and effective discharging capacitance. Taking a capacitor C1 of 100 nF as an example, the non-linear capacitor proposed in the present application has an effective charging capacitance which is about 22 μF and an effective discharging capacitance which is about 620 pF. Thus, the charging time and discharging time can be configured more flexibly.

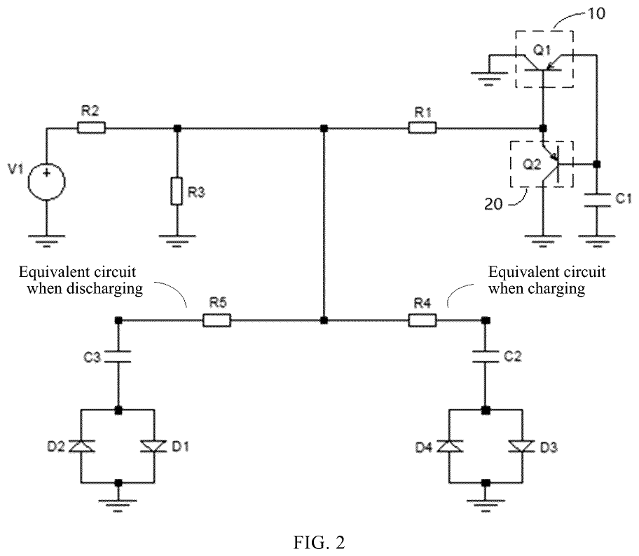

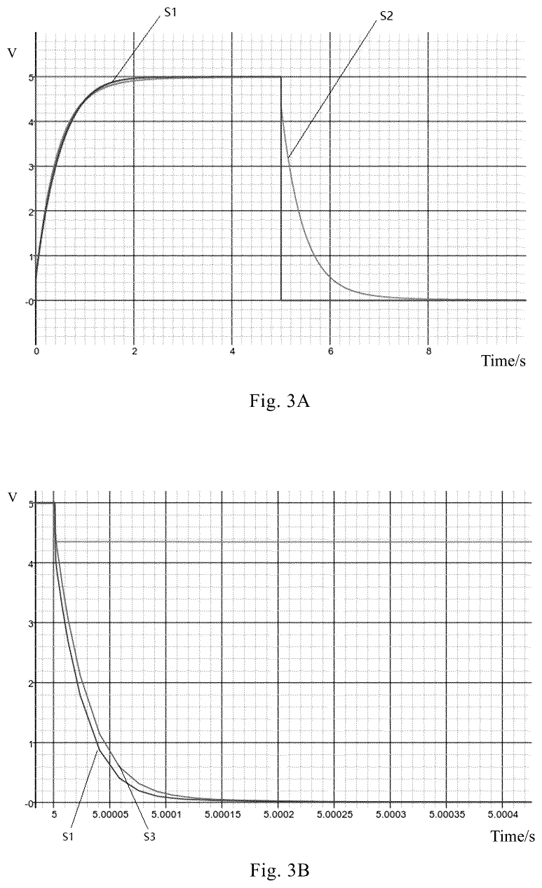

The asymmetric capacitor of the present application is simulated by the circuit shown in FIG. 2. Wherein the voltage source V1 and a second resistor R2 form a 5052 pulse generator, which is connected to a third resistor R3 of 5052. A second capacitor C2 and a fourth resistor R4 are an RC network having a charging time which is equivalent to the asymmetric capacitor consisting of the first resistor R1, the capacitor C1, the first PNP transistor Q1 and the second PNP transistor Q2. The third capacitor C3 and a fifth resistor R5 are an RC network having a discharging time which is equivalent to the asymmetric capacitor consisting of the first resistor R1, the capacitor C1, the first PNP transistor Q1 and the second PNP transistor Q2. Diodes D1, D2 have voltages that are approximate or equal to the base-emitter voltage of the first PNP transistor Q1, and diodes D3, D4 have voltages that are approximate or equal to the base-emitter voltage of the second PNP transistor Q2. The second capacitor is of 11 μF and the third capacitor is of 600 pF. That is, the effective charging capacitance is 11 μF and the effective discharging capacitance is 600 pF. The simulation results are shown in FIG. 3A and FIG. 3B, wherein S1, S2, and S3 represent the curves of simulation results of the asymmetric capacitor of the present application, the equivalent charging RC network and the equivalent discharging RC network respectively. The asymmetric capacitor has a charging time of 517 ms that is approximately as same as the 47kΩ, 11 μF network with R4 and C2, and has a discharging time of 28.2 us that is approximately as same as the 47kΩ, 600 pF network with R5 and C3.

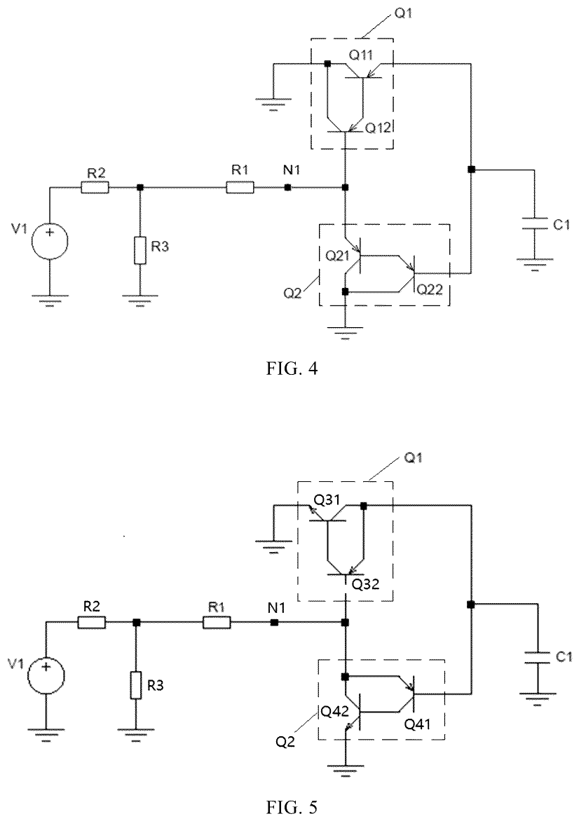

In an embodiment, a Darlington pair may be used to form the asymmetric capacitor of the present application. As shown in FIG. 4, the first PNP transistor Q1 and the second PNP transistor Q2 are connected as a Darlington pair. It should be understood that a Darlington pair represents the transistor combination of two transistors, and the gain of a Darlington pair is the product of the gains of the two transistors.

Similar to the circuit shown in FIG. 1, Darlington-connected transistors Q21, Q22 charge the capacitor C1, the effective charging time constant is about: R1·C1 (β₂₁·β₂₂), and this effective charging time constant is obtained from the above formula (1).

Darlington-connected transistors Q11, Q12 discharge the capacitor C1, the effective discharging time constant is about: R1·C1/(β₁₁·β₁₂), and this effective discharging time constant is obtained from the above formula (2).

In some embodiments, a Darlington pair, such as MMBTA13 and MMBTA14, may be used. In other embodiments, an on-chip Super-Beta transistor with a base-emitter voltage drop may also be used to provide an extremely high gain.

In an embodiment, a Sziklai pair may be used to form the asymmetric capacitor. As shown in FIG. 5, both the first PNP transistor Q1 and the second PNP transistor Q2 are connected as a Sziklai pair. It should be understood that a Sziklai pair represents the transistor combination of two semiconductor types (such as NPN and PNP). The gain of the Sziklai pair is the product of the gains of the two transistors.

Sziklai-connected transistors Q41, Q42 charge the capacitor C1, the effective charging time constant is about: R1·C1 (β₄₁·β₄₂), and this effective charging time constant is obtained from the above formula (1).

Sziklai-connected transistors Q31, Q32 discharge the capacitor C1, an effective discharging time constant is about: R1·C1/(β₃₁·β₃₂), this effective discharging time constant is obtained from the above formula (2).

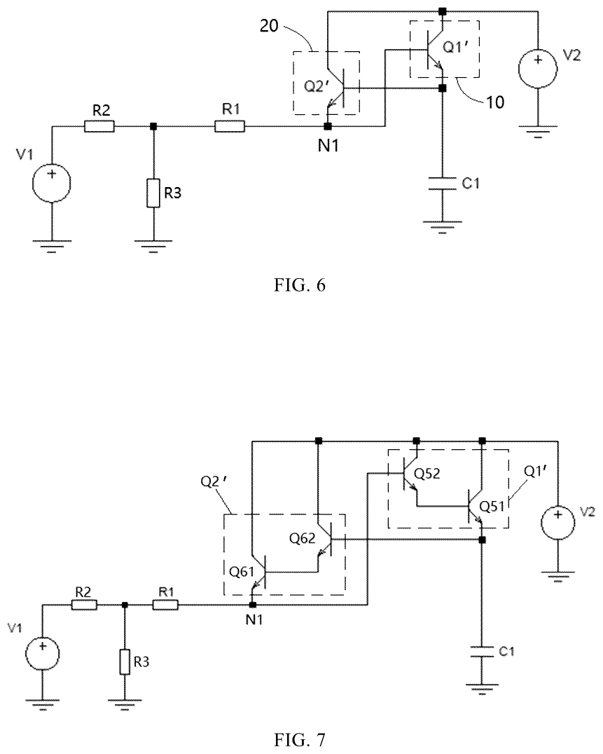

FIG. 6 is a circuit diagram of a non-linear capacitor according to an embodiment of the present application. Refer to FIG. 6, the first amplifier device 10 can be a first NPN transistor Q1′, and the second amplifier device 20 can be a second NPN transistor Q2′. An emitter of the first NPN transistor Q1′ and a base of the second NPN transistor Q2′ are connected to an end of the capacitor C1, and a base of the first NPN transistor Q1′ and an emitter of the second NPN transistor Q2′ are connected to the input and output node N1. A collector of the first NPN transistor Q1′ is connected to a second reference voltage, and a collector of the second NPN transistor Q2′ is connected to a third reference voltage. In the present embodiment, the second reference voltage and the third reference voltage are the voltage source V2.

When the capacitor C1 is charging, the second NPN transistor Q2′ is cut off. The first NPN transistor Q1′ is conducted. Since the operation of the first NPN transistor Q1′ satisfies the following formula:

Iₑ₁′=I_{b1}′+I_{c1}′ and I_{c1}′=β₁′·I_{b1}′, wherein β₁′ is a current gain of the first NPN transistor Q1′; I_{b1}′, Iₑ₁′ and I_{c1}′ are the base current, the emitter current, and the collector current of the first NPN transistor Q1′, respectively.

The current gain of the first NPN transistor Q1′ increases the emitter current Iₑ₁ which is the charging current of the capacitor C1, thus the charging time constant is about: R1·C1/β₁′ when charging.

When the capacitor C1 is discharging, the first NPN transistor Q1′ is cut off, and the second NPN transistor Q2′ is conducted. The current gain of the second NPN transistor Q2′ increases the discharging current of the capacitor C1, thus the discharging time constant is about: R1·C1·β₂′ when discharging, wherein β₂′ is a current gain of the second NPN transistor Q2′.

According to the above, a “dual circuit” (or “complementary circuit”) operation with fast charging and slow discharging is achieved by using the first NPN transistor Q1′ and the second NPN transistor Q2′.

In an embodiment, a Darlington pair may be used for fast charging and slow discharging. As shown in FIG. 7, both the first NPN transistor Q1′ and the second NPN transistor Q2′ are connected as a Darlington pair.

Darlington-connected transistors Q51, Q52 charge the capacitor C1, and the effective charging time constant is about: R1·C1/(β₅₁·β₅₂).

Similarly, Darlington-connected transistors Q61, Q62 discharge the capacitor C1, and the effective discharging time constant is about: R1·C1(β₆₁·β₆₂).

In some embodiments, a Darlington pair such as MMBTA13, MMBTA14 may be used. In other embodiments, an on-chip Super-Beta transistor with a base-emitter voltage drop may also be used to provide extremely high gain.

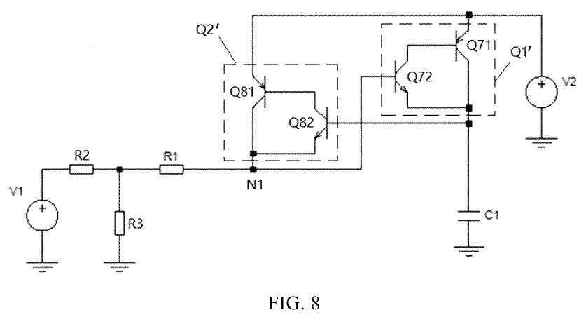

In an embodiment, a Sziklai pair may be used for fast charging and slow discharging. As shown in FIG. 8, both the first NPN transistor Q1′ and the second NPN transistor Q2′ are connected as a Sziklai pair.

Sziklai-connected transistors Q71, Q72 charge the capacitor C1, and the effective charging time constant is about: R1·C1/(β₇₁·β₇₂).

Similarly, Sziklai-connected transistors Q81, Q82 discharge the capacitor C1, and the effective discharging time constant is about: R1·C1(β₈₁·β₈₂).

The foregoing is only preferred embodiments of the present application and is not intended to limit the present application, and any modifications, equivalent substitutions, improvements and the like within the spirit and principles of the present application are intended to be embraced by the protection scope of the present application.

1. A non-linear capacitor, comprising:
a capacitor;
an input and output node for providing a charging current and a discharging current;
a first amplifier device connecting the capacitor and the input and output node; and
a second amplifier device connecting the capacitor and the input and output node,
wherein, when the capacitor is charging, one of the first and the second amplifier devices is conducted to vary the charging current, and the capacitor is charged by the varied charging current,
wherein, when the capacitor is discharging, an other of the first and the second amplifier devices is conducted to vary the discharging current, and the capacitor is discharged by the varied discharging current, and
wherein a variation trend of the charging current is opposite to a variation trend of the discharging current.

2. The non-linear capacitor according to claim 1, wherein the first amplifier device is a first NPN transistor and the second amplifier device is a second NPN transistor,
wherein an emitter of the first NPN transistor and a base of the second NPN transistor are connected to an end of the capacitor, and
wherein a base of the first NPN transistor and an emitter of the second NPN transistor are connected to the input and output node.

3. The non-linear capacitor according to claim 2, wherein an effective charging capacitance C_{charge} and an effective discharging capacitance C_{discharge} respectively are:
$${C}_{discharge} = ( {β}_{2} + 1 ) C 1 , and {C}_{charge} = C 1 / ( β 1 + 1 ) ,$$
and
wherein β1 is a current gain of the first NPN transistor, and β2 is a current gain of the second NPN transistor.

4. The non-linear capacitor according to claim 2, wherein the first NPN transistor and the second NPN transistor are connected as a Darlington pair.

5. The non-linear capacitor according to claim 2, wherein the first NPN transistor and the second NPN transistor are connected as a Sziklai pair.

6. The non-linear capacitor according to claim 1, wherein the first amplifier device is a first PNP transistor and the second amplifier device is a second PNP transistor,
wherein an emitter of the first PNP transistor and a base of the second PNP transistor are connected to an end of the capacitor, and
wherein a base of the first PNP transistor and an emitter of the second PNP transistor are connected to the input and output node.

7. The non-linear capacitor according to claim 6, wherein an effective charging capacitance C_{charge} and an effective discharging capacitance C_{discharge} respectively are:
$${C}_{charge} = ( β 2 + 1 ) C 1 , and {C}_{discharge} = C 1 / ( β 1 + 1 ) ,$$
and
wherein β1 is a current gain of the first PNP transistor, and β2 is a current gain of the second PNP transistor.

8. The non-linear capacitor according to claim 6, wherein the first PNP transistor and the second PNP transistor are connected as a Darlington pair.

9. The non-linear capacitor according to claim 6, wherein the first PNP transistor and the second PNP transistor are connected as a Sziklai pair.

10. The non-linear capacitor according to claim 1, wherein the non-linear capacitor further comprises a resistor connected to the input and output node.

11. A non-linear capacitor, comprising:
a capacitor having a first end;
a first transistor having an emitter and a base;
a second transistor having an emitter and a base; and
an input and output node for providing a charging current and a discharging current,
wherein the emitter of the first transistor and the base of the second transistor are connected to the first end of the capacitor, and the base of the first transistor and the emitter of the second transistor are connected to the input and output node, and
wherein one of the first transistor and the second transistor is conducted and an other of the first transistor and the second transistor is cut off when the capacitor is charging, and the one of the first transistor and the second transistor is cut off and the other of the first transistor and the second transistor is conducted when the capacitor is discharging.

12. The non-linear capacitor according to claim 11, wherein the first transistor and the second transistor are NPN transistors, and
wherein the first transistor is conducted when the capacitor is charging, and the second transistor is conducted when the capacitor is discharging.

13. The non-linear capacitor according to claim 11, wherein the first transistor and the second transistor are PNP transistors, wherein the second transistor is conducted when the capacitor is charging, and the first transistor is conducted when the capacitor is discharging.

14. The non-linear capacitor according to claim 11, further comprising a resistor connected to the input and output node.

15. The non-linear capacitor according to claim 1, wherein the first transistor and the second transistor are connected as a Darlington pair or a Sziklai pair.
